(19) United States
(12) Patent Application Publication
(10) Pub. No.: US 2009/0261476 A1
(43) Pub. Date: Oct. 22, 2009

(54) Semiconductor device and manufacturing method thereof

(75) Inventors: Chien-Ping Huang, Taichung (TW); Chin-Huang Chang, Taichung Hsien (TW); Chih-Ming Huang, Hsinchu Hsein (TW); Cheng-Hsu Hsiao, Taichung Hsien (TW); Chun-Chi Ke, Taichung Hsein (TW)

Correspondence Address: Edwards Angell Palmer & Dodge LLP, P. O. Box 55874, Boston, MA, 02205, US

(73) Assignee: Siliconware Precision Industries Co., Ltd., Taichung (TW)

(21) Appl. No.: 12/148,319

(22) Filed: Apr. 18, 2008

(30) Foreign Application Priority Data
Apr. 18, 2008 (TW) 096113588

(51) Int. Cl. H01L 23/482; H01L 21/60

(52) U.S. Cl. 257/766; 438/107; 257/E23.017; 257/E21.506

(57) ABSTRACT

A semiconductor device and a manufacturing method thereof are disclosed. The method includes the steps of providing a carrier board having conductive circuits disposed thereon and a plurality of chips with active surfaces having solder pads disposed thereon, wherein conductive bumps are disposed on the solder pads; mounting chips on the carrier board; filling the spacing between the chips with a dielectric layer and forming openings in the dielectric layer at periphery of each chip to expose the conductive circuits; forming a metal layer in the openings of the dielectric layer and at periphery of the active surface of the chips for electrically connecting the conductive bumps and the conductive circuits; and cutting along the dielectric layer between the chips and removing the carrier board to separate each chip and exposing the conductive circuits from the non-active surface.

### BACKGROUND OF THE INVENTION

1. Field of the Invention

The present invention relates to a semiconductor device and a manufacturing method thereof, and more particularly to vertically stacked semiconductor devices and a manufacturing method thereof.

2. Description of Related Art

An MCM (Multi-chip Module) semiconductor package typically includes more than two chips mounted to a substrate or a lead-frame. The MCM semiconductor packages can meet requirement such as high integration and miniaturization of semiconductor packages and meanwhile improve performance and capacity of single semiconductor packages, thereby facilitating fabrication of various portable electronic products and peripheral products in the areas such as communication, network and computers.

FIG. 1 shows a conventional multi-chip semiconductor package with horizontally spaced chips. As shown in FIG. 1, the package includes a substrate 100, a first chip 110 having an active surface 110a and a non-active surface 110b opposing to the active surface 110a, wherein the non-active surface 110b of the first chip 110 is attached to the substrate 100 and the active surface 110a of the first chip 110 is electrically connected to the substrate 100 through first conductive wires 120, and a second chip 140 having an active surface 140a and a non-active surface 140b opposing to the active surface 140a, wherein the non-active surface 140b of the second chip 140 is attached to the substrate 100 and the active surface 140a of the second chip 140 is electrically connected to the substrate 100 through second conductive wires 150. The second chip 140 is spaced at a certain interval from the first chip 110.

One drawback of the above-described multi-chip semiconductor package is that the chips must be spaced from each other at a certain interval to prevent wire miscontact between the chips. Accordingly, when there are a plurality of chips to be attached to the substrate, a large die attachment area must be defined in order to accommodate the chips. Thus, the manufacturing cost is increased and it is difficult to meet demands for thinner, shorter, smaller and lighter electronic products.

FIG. 2 shows a semiconductor package disclosed in U.S. Pat. No. 6,538,331, wherein a first chip 210 and a second chip 240 are stacked on a substrate 200 and the second chip 240 is offset a certain interval from the first chip 210 so as to facilitate bonding of wires 220, 250 from the first and second chips 210, 240 to the substrate 200, respectively.

Such a stack structure saves much more substrate spaces compared with semiconductor packages with horizontally spaced chips. However, since the chips and the substrate of the package are electrically connected together by wire bonding, length of the bond wires influences quality of the electrical connection between the chips and the substrate and even leads to poor electrical connection. Further, the amount of the chips that can be accommodated in the package is limited by spaces required by chip offset and wire bonding.

Therefore, U.S. Pat. No. 6,642,081, No. 5,270,261 and No. 6,809,421 disclose the use of a TSV (Through Silicon Via) technique to vertically stack a plurality of chips and establish electrical connections between the chips. However, as the TSV technique is too complicated and costly, its practical use in the industry is limited. In addition, U.S. Pat. No. 5,716,759, No. 6,040,235, No. 5,455,455, No. 6,646,289, and No. 6,777,767 disclose a chip with conductive circuits disposed on opposing upper and lower surfaces thereof. Cut grooves are formed on the non-active surface of a wafer having a plurality of chips. A sputtering technique is used for forming electrical connection between solder pads on the active surface of each chip and the non-active surface thereof through a redistribution layer (RDL). However, cut grooves on the non-active surface (backside) of the wafer makes it difficult to realize precise alignment and results in offset of position of subsequently formed circuits. Thus, the electrical connection between the active surface and the non-active surface of each chip is affected, and even the chip is damaged. Also, as the circuit redistribution layer (RDL) technique is used several times in the process, it makes the manufacturing process complicated and increases the manufacturing cost. Furthermore, as the manufacturing process is directly performed on a wafer without taking into account of quality of the chips, if some chip of the wafer is defective, the continued manufacturing process will result in such problems as material waste and cost increase.

Therefore, there is a need to develop a semiconductor device and a manufacturing method thereof such that much more chips can be efficiently integrated without increasing area so as to improve electrical performance and eliminate the wire bonding technique, the TSV technique and multiple sputtering technique in order to simplify manufacturing process, reduce manufacturing cost, and overcome the conventional drawback such as performing the manufacturing process directly on wafer without taking into account of quality of chips.

### SUMMARY OF THE INVENTION

According to the above drawbacks, an objective of the present invention is to provide a semiconductor device and a manufacturing method thereof for efficiently integrating much more chips without increasing area.

Another objective of the present invention is to provide a semiconductor device and manufacturing method thereof, which simplifies manufacturing process without using the sputtering process for several times as in the prior art and accordingly eliminates the complicated manufacturing process and high manufacturing cost in the prior art.

Another objective of the present invention is to provide a semiconductor device and a manufacturing method thereof, in which a plurality of semiconductor, chips can be vertically stacked and electrically connected together without using the conventional wire bonding technique and the TSV technique, thereby preventing the conventional problems such as poor electrical performance caused by using the wire bonding technique, and complicated manufacturing process and high manufacturing cost caused by using the TSV technique.

A further objective of the present invention is to provide a semiconductor device and a manufacturing method thereof for ensuring that chips to be used have good quality.

Still another objective of the present invention is to provide a semiconductor device and a manufacturing method thereof with low cost and simplified manufacturing process.

A further objective of the present invention is to provide a semiconductor device and a manufacturing method thereof for preventing the conventional problem of chip damage caused by cut grooves formed at back side of a wafer.

In order to attain the above and other objectives, the present invention provides a manufacturing method of a semiconductor device. The manufacturing method of the present invention includes the steps of providing a carrier board having a plurality of conductive circuits disposed thereon and a plurality of chips with active surfaces having solder pads disposed thereon, wherein conductive bumps are disposed on the solder pads, the chips are mounted on the carrier board and spaced away from each other, and cover one end of each conductive circuit, and the conductive circuits are exposed from spacing between the chips; filling the spacing between the chips with a dielectric layer and forming a plurality of openings in the dielectric layer at periphery of the chips so as to expose a part of the conductive circuits; forming a resist layer covering surfaces of the chips and the dielectric layer and forming openings in the resist layer so as to expose regions from the conductive bumps of the chips to the openings of the dielectric layer; forming a metal layer in the openings of the dielectric layer and the resist layer for electrically connecting the conductive bumps and the conductive circuits; and removing the resist layer, cutting along the dielectric layer between the chips and removing the carrier board so as to separate the chips from each other and expose the conductive circuits from non-active surface of the chips.

The manufacturing method of the present invention further comprises the steps of: providing a wafer having a plurality of chips, wherein each chip has an active surface and a non-active surface opposing to the active surface, a plurality of solder pads are disposed on the active surface of each chip, and after a test is performed to determine each chip is a good die, conductive bumps are mounted on the solder pads of each good die; thinning the non-active surface of the wafer for the wafer to be attached to a tape; and singulating the wafer so as to take out the good die and mounting the good die to the carrier board interposed with an adhesive layer.

The carrier board is a metal board, and the conductive circuits are formed as Au/Ni/Au structures disposed on the carrier board. Accordingly, through an electroplating process, the metal layer can be formed in the openings of the dielectric layer and the resist layer for electrically connecting the conductive bumps of each chip and the conductive circuits. The metal layer includes a copper layer, a nickel layer and a solder layer in sequence. Thereafter, the metal layer on the active surface of the chip of one semiconductor device can be electrically connected to the conductive circuits on the non-active surface of the chip of another semiconductor device so as to form a multi-chip stack structure.

Further, after the metal layer is formed and the resist layer is removed, a insulation layer can be formed on the active surface of the chips and the metal layer, and then the carrier board is removed and the structure is cut along the dielectric layer between the chips so as to separate the chips from each other, thereby forming a thin-type chip scale semiconductor device. Moreover, conductive components can be mounted on the conductive circuits of the non-active surface of the chips. The conductive components can be used for electrical connection with an external device or directly used for stack of semiconductor devices.

In accordance with the above-described manufacturing method, the present invention further provides a semiconductor device. The semiconductor device of the present invention includes a chip having an active surface and a non-active surface opposing to the active surface, a plurality of solder pads disposed on the active surface of the chip and conductive bumps disposed on the solder pads; conductive circuits formed on the non-active surface of the chip; a dielectric layer formed at sides of the chip and having openings for exposing a part of the conductive circuits; and a metal layer formed in the openings of the dielectric layer and at periphery of the active surface of the chip for electrically connecting the conductive bumps of the chip and the conductive circuits. In addition, an adhesive layer is formed between the non-active surface of the chip and the conductive circuits, and the conductive circuits are relatively disposed at periphery of the adhesive layer.

The semiconductor device further includes an insulation layer covering the active surface of the chip and the metal layer, and conductive components mounted on outer surface of the conductive circuits so as to form a thin-type chip scale semiconductor device.

Therefore, according to the present invention, a carrier board has a plurality of conductive circuits disposed thereon, a plurality of chips has active surfaces having solder pads disposed thereon, wherein conductive bumps are disposed on the solder pads, the chips are mounted on the carrier board and cover one end of each conductive circuit and the conductive circuits are exposed from spacing between the chips, wherein the chips are confirmed as good die so as to avoid performing the manufacturing process on defective chips as in the prior art. Thus, the present invention reduces material and cost. Further, the spacing between the chips is filled with a dielectric layer and a plurality of openings are formed in the dielectric layer at periphery of each chip to expose a part of the conductive circuits. Subsequently, a resist layer is formed to cover surfaces of the chips and the dielectric layer, a plurality of openings are formed in the resist layer to expose regions from the conductive bumps on each chip to the openings of the dielectric layer, and a metal layer is formed in the openings of the dielectric layer and the resist layer by electroplating for electrically connecting the conductive bumps and the conductive circuits. Hence, it is eliminated in the present invention to use the sputtering process for several times. Accordingly, the manufacturing process is simplified and the manufacturing cost is reduced. Moreover, the resist layer is removed, the structure is cut along the dielectric layer between the chips and the carrier board is removed so as to separate the chips from each other and expose the conductive circuits from the non-active surface of the chips, thereby obtaining a plurality of semiconductor devices of the present invention. In the present invention, the conductive circuits exposed from the non-active surface of the chip of one semiconductor device can be mounted and electrically connected to a chip carrier, and then the conductive circuits exposed from the non-active surface of the chip of another semiconductor device can be mounted and electrically connected to the metal layer of the above-mentioned semiconductor device so as to form a multi-chip stack structure that is vertically stacked without increasing the stack area. Thus, multiple chips can be efficiently integrated in the stack structure so as to improve electrical performance. Also, as the present invention avoids use of the wire bonding technique and the TSV technique, poor electrical performance resulting from the wire bonding technique and complicated manufacturing process and high cost caused by the TSV technique are prevented.

### BRIEF DESCRIPTION OF DRAWINGS

FIG. 1 is a sectional view of a conventional semiconductor package with multiple chips horizontally spaced from each other;

FIG. 2 is a sectional view of a semiconductor package with stacked chips disclosed in U.S. Pat. No. 6,538,331;

FIGS. 3A to 3G are sectional view showing a semiconductor device and manufacturing method thereof according to the first embodiment of the present invention, wherein FIG. 3D′ is a partially enlarged diagram of FIG. 3D;

FIG. 4 is a diagram showing a stack structure of the semiconductor devices according to the first embodiment of the present invention;

FIGS. 5A and 5B are sectional views showing a semiconductor device and a manufacturing method thereof according to the second embodiment of the present invention; and

FIG. 6 is a diagram showing a stack structure of the semiconductor devices according to the second embodiment of the present invention.

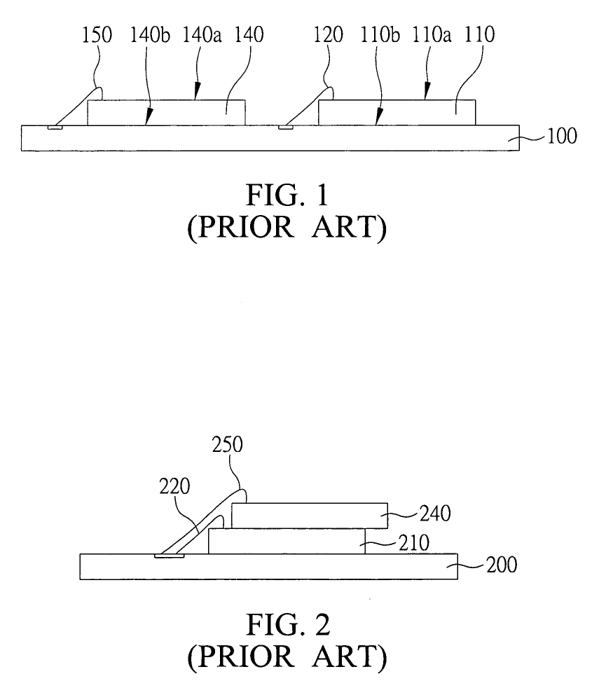

### DETAILED DESCRIPTION OF PREFERRED EMBODIMENTS

The following illustrative embodiments are provided to illustrate the disclosure of the present invention, these and other advantages and effects can be apparent to those skilled in the art after reading the disclosure of this specification. The present invention can also be performed or applied by other different embodiments. The details of the specification may be on the basis of different points and applications, and numerous modifications and variations can be made without departing from the spirit of the present invention.

### First Embodiment

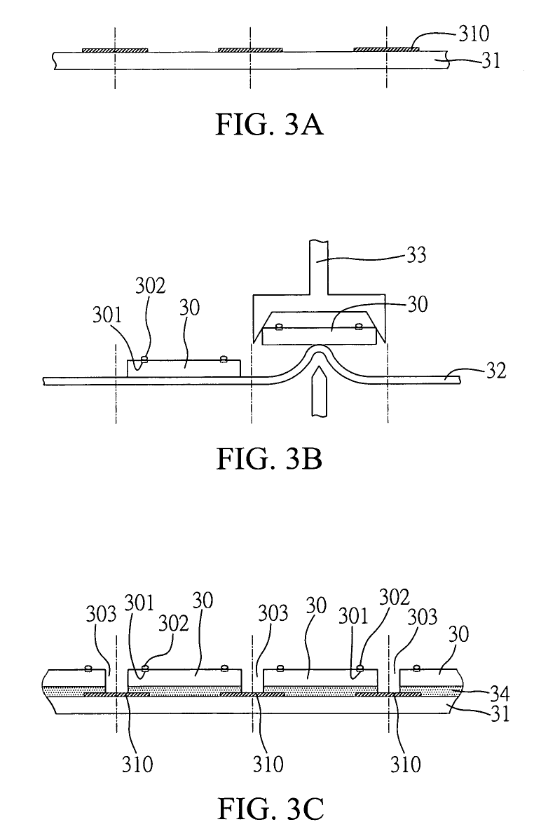

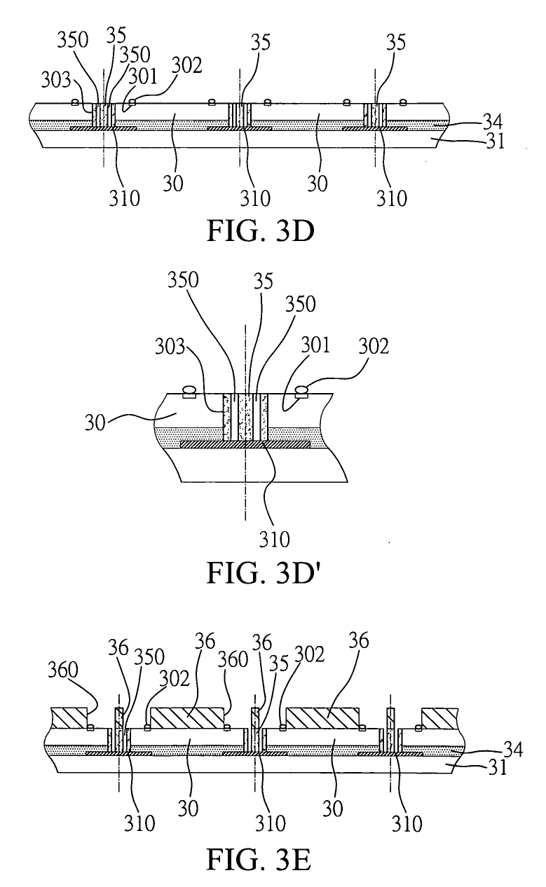

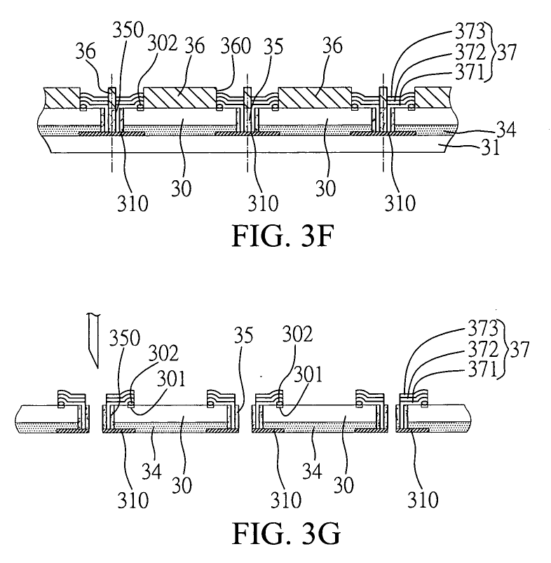

FIGS. 3A to 3G are diagrams showing a semiconductor device and a manufacturing method thereof according to the first embodiment of the present invention.

As shown in FIG. 3A, a carrier board 31 having a plurality of conductive circuits 310 is provided. The carrier board 31 is a metal plate made of copper, for example. The conductive circuits 310 can be formed on the carrier board 31 by electroplating. The conductive circuit 310 is an Au/Ni/Au structure, and has a thickness of approximately 0.5 to 3 μm.

As shown in FIG. 3B, a wafer having a plurality of chips 30 is provided. Each chip 30 has an active surface and a non-active surface opposing to the active surface, and a plurality of solder pads 301 are disposed on the active surface of the chip 30. A chip probing (CP) test is performed to determine whether each chip is a good die. Conductive bumps 302 such as Au studs are mounted on the solder pads 301 of the good die. The non-active surface of the wafer is thinned and attached to a tape 32. Then, the wafer is singulated, and the good die 30 is taken out by a clip device 33. As shown in FIG. 3C, the chip 30, which is a good die, is attached to the carrier board 31 through its non-active surface, and an adhesive layer 34 is interposed between the chip 30 and the carrier board 31. The spacing 303 is formed between the chips 30. The chips 30 cover one end of each conductive circuits 310, and the conductive circuits 310 are exposed from the spacing 303. For example, the adhesive layer 34 can be made of B-stage epoxy resin.

As shown in FIGS. 3D and 3D′, wherein FIG. 3D′ is a partially enlarged view of FIG. 3D, a dielectric layer 35 made of epoxy resin or polyimide is filled in the spacing 303 between the chips 30, and a plurality of openings 350 are formed in the dielectric layer 35 disposed at periphery of each chip 30 by laser or etching so as to expose a part of the conductive circuits 310. The openings 350 are spaced away from sides of the corresponding chips 30, such that the sides of the chips 30 are covered by the dielectric layer 35 so as to isolate a metal layer to be formed later from the chips 30.

As shown in FIG. 3E, a resist layer 36 such as a dry film is formed on surfaces of the chips 30 and the dielectric layer 35, and a plurality of openings 360 are formed in the resist layer 36 for exposing the regions from the conductive bumps 302 of each chip to the openings 350 of the dielectric layer 35.

As shown in FIG. 3F, by performing an electroplating process and using the carrier board 31 made of metal material and the conductive circuits 310, a metal layer 37 is deposited in the openings 350 of the dielectric layer 35 and the openings 360 of the resist layer 36, such that the conductive bumps 302 of each chip 30 can be electrically connected to the conductive circuits 310 through the metal layer 37. The metal layer 37 includes a copper layer 371, a nickel layer 372 and a solder layer 373 in sequence. The copper layer 371 is deposited in the openings 350 of the dielectric layer 35 and covers the regions from periphery of active surface of the chips 30 to the conductive bumps 302, and then the nickel layer 372 and the solder layer 373 are deposited on the copper layer 371.

As shown in FIG. 3G, the resist layer 36 is removed, the structure is cut along the dielectric layer 35 between the chips 30, and the carrier board 31 is removed by etching. Thus, the chips 30 are separated from each other and the conductive circuits 310 are exposed from non-active surface of the chips 30, thereby obtaining a plurality of semiconductor devices of the present invention.

In accordance with the above-described method, the present invention further provides a semiconductor device. The semiconductor device includes a chip 30 having an active surface and a non-active surface opposing to the active surface, a plurality of solder pads 301 disposed on the active surface of the chip 30 and conductive bumps 302 disposed on the solder pads 301. In the semiconductor device of the present invention, conductive circuits 310 are formed on the non-active surface of the chip 30, a dielectric layer 35 is formed at sides of the chip 30 and has openings 350 for exposing a part of the conductive circuits 310, and a metal layer 37 is formed in the openings 350 of the dielectric layer 35 and at periphery of the active surface of the chip 30 for electrically connecting the conductive bumps 302 and the conductive circuits 310. An adhesive layer 34 is further formed between the non-active surface of the chip 30 and the conductive circuits 310, and the conductive circuits 310 are relatively disposed at periphery of the adhesive layer 34.

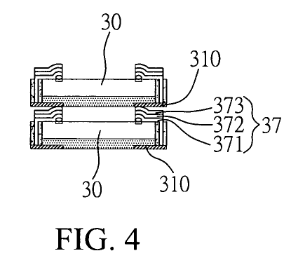

Further, as shown in FIG. 4, at least two above-described semiconductor devices are stacked together, and by using a thermal compression technique, the solder layer 373 of the metal layer 37 on the active surface of the chip 30 of one semiconductor device is melted to the conductive circuits 310 on the non-active surface of the chip 30 of another semiconductor device, thereby forming a multi-chip stack structure. In addition, an underfill material (not shown) can be filled between the two semiconductor devices of the multi-chip stack structure so as to strengthen bonding between the semiconductor devices.

### Second Embodiment

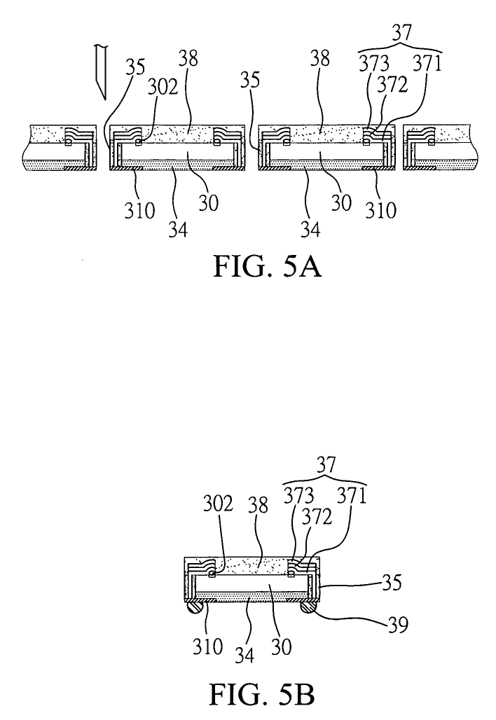

FIGS. 5A and 5B are diagrams showing a semiconductor device and a manufacturing method thereof according to the second embodiment of the present invention. To simplify the drawings, components of the present embodiment that are same as or similar to those of the first embodiment are denoted by the same reference numerals.

As shown in FIG. 5A, a main difference of the present embodiment from the first embodiment is that after the metal layer 37 is formed and the resist layer is removed, an insulation layer 38 is further formed to cover the active surface of the chips 30 and the metal layer 37. The insulation layer 38 may be made of an epoxy resin, for example. The carrier board is then removed by etching, and the structure is cut along the dielectric layer 35 between the chips so as to separate the chips from each other, thereby forming a plurality of thin-type chip scale semiconductor devices.

As shown in FIG. 5B, conductive components 39 such as solder balls are further mounted on the conductive circuits 310 of the non-active surface of the chip 30 such that the chip 30 can be electrically connected to an external device through the conductive components 39.

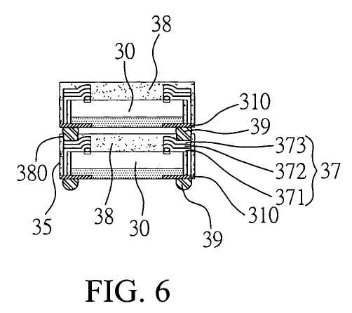

Further, referring to FIG. 6, the insulation layer 38 of the above-described semiconductor device may have openings 380 formed for exposing the metal layer 37. The metal layer 37 is electrically connected to the conductive bumps 39 mounted on the conductive circuits 310 of another semiconductor device. Thus, a stack structure of semiconductor devices is formed.

Therefore, the present invention provides a carrier board having a plurality of conductive circuits disposed thereon and a plurality of chips with active surfaces having solder pads thereon, wherein conductive bumps are disposed on the solder pads. Also, the chips are mounted on the carrier board and cover one end of each conductive circuit, and the conductive circuits are exposed from spacing between the chips, wherein the chips are confirmed as good die so as to avoid performing the manufacturing process on defective chips as in the prior art. Thus, the material and cost are reduced in the present invention. Further, the spacing between the chips is filled with a dielectric layer and a plurality of openings are formed in the dielectric layer at periphery of each chip to expose a part of the conductive circuits. Subsequently, a resist layer is formed to cover surfaces of the chips and the dielectric layer, a plurality of openings are formed in the resist layer to expose the regions from the conductive bumps of each chip to the openings of the dielectric layer, and a metal layer is formed in the openings of the dielectric layer and the resist layer by electroplating for electrically connecting the conductive bumps and the conductive circuits, thereby avoiding using the sputtering process for several times and accordingly simplifying the manufacturing process and saving the manufacturing cost. Furthermore, the resist layer is then removed, the structure is cut along the dielectric layer between the chips, and the carrier board is removed so as to separate the chips from each other and expose the conductive circuits from the non-active surface of the chips. Therefore, a plurality of semiconductor devices of the present invention are formed by a low-cost and simple process. Thereafter, the conductive circuits exposed from the non-active surface of the chip of one semiconductor device can be mounted and electrically connected to a chip carrier, and then the conductive circuits exposed from the non-active surface of the chip of another semiconductor device can be mounted and electrically connected to the metal layer of the above-described semiconductor device so as to form a multi-chip stack structure that is vertically stacked without increasing the stack area. Thus, multiple chips can be efficiently integrated in the stack structure so as to improve electrical performance. Moreover, as the present invention avoids using the wire bonding technique and the TSV technique, poor electrical performance resulting from the wire bonding technique and complicated manufacturing process and high cost caused by the TSV technique are prevented.

The above-described descriptions of the detailed embodiments are only to illustrate the preferred implementation according to the present invention, and it is not to limit the scope of the present invention, Accordingly, all modifications and variations completed by those with ordinary skill in the art should fall within the scope of present invention defined by the appended claims.

What is claimed is:

1. A manufacturing method of a semiconductor device, comprising the steps of:
providing a carrier board having a plurality of conductive circuits disposed thereon and a plurality of chips with active surfaces having solder pads thereon, wherein conductive bumps are disposed on the solder pads;
mounting the chips on the carrier board, wherein the chips are spaced away from each other and cover one end of each of the conductive circuits, so as to expose the conductive circuits from spacing between the chips;
filling the spacing between the chips with a dielectric layer, and forming a plurality of openings in the dielectric layer at periphery of the chips so as to expose a part of the conductive circuits;
forming a resist layer covering surfaces of the chips and the dielectric layer, and forming openings in the resist layer for exposing the conductive bumps to the openings of the dielectric layer;
forming a metal layer in the openings of the dielectric layer and the resist layer for electrically connecting the conductive bumps of the chips and the conductive circuits; and
removing the resist layer, cutting along the dielectric layer between the chips and removing the carrier board for separating the chips from each other and exposing the conductive circuits from non-active surfaces of the chips.

2. The manufacturing method of claim 1, wherein the carrier board is a metal board, and the conductive circuits are formed as an Au/Ni/Au structure on the carrier board by electroplating.

3. The manufacturing method of claim 1, further comprising the steps of:
providing a wafer having the plurality of chips, wherein each chip has an active surface and a non-active surface opposing to the active surface, the solder pads are disposed on the active surface of each chip, and after a test is performed to determine each chip being a good die, conductive bumps are mounted on the solder pads of the good die;
thinning the non-active surface of the wafer for the wafer to be attached to a tape; and
singulating the wafer so as to take out the good die and mounting the good die to the carrier board, wherein an adhesive layer is interposed between the good die and the carrier board.

4. The manufacturing method of claim 1, wherein the dielectric layer is made of one of an epoxy resin and polyimide, and the resist layer is a dry film.

5. The manufacturing method of claim 1, wherein the openings in the dielectric layer at periphery of the chips are formed by one of laser and etching for exposing the part of the conductive circuits, and the openings of the dielectric layer are spaced away from sides of the chips such that the sides of the chips are covered by the dielectric layer.

6. The manufacturing method of claim 1, wherein the metal layer comprises a copper layer, a nickel layer and a solder layer, and is formed by depositing the copper layer in the openings of the dielectric layer via electroplating to cover regions from periphery of active surfaces of the chips to the conductive bumps and depositing the nickel layer and the solder layer on the copper layer.

7. The manufacturing method of claim 1, wherein a thermal compression is performed such that the metal layer on the active surface of the chip of one semiconductor device is electrically connected to the conductive circuits on the non-active surface of the chip of another semiconductor device, thereby forming a multi-chip stack structure.

8. The manufacturing method of claim 7, wherein an underfill material is filled in the spacing between the semiconductor devices of the stack structure.

9. The manufacturing method of claim 1, further comprising the steps of:
forming an insulation layer on the active surfaces of the chips and the metal layer after the metal layer is formed and the resist layer is removed; and
removing the carrier board and cutting along the dielectric layer between the chips so as to separate the chips from each other.

10. The manufacturing method of claim 9, wherein conductive components are mounted on outer surface of the conductive circuits on the non-active surface of the chips.

11. The manufacturing method of claim 10, wherein the insulation layer has openings formed to expose the metal layer, and the conductive components mounted on the conductive circuits of another semiconductor device are electrically connected to the metal layer exposed from the insulation layer.

12. A semiconductor device, comprising:
a chip having an active surface and a non-active surface opposing to the active surface, a plurality of solder pads disposed on the active surface, and conductive bumps disposed on the solder pads;
conductive circuits formed on the non-active surface of the chip;
a dielectric layer formed at sides of the chip, and having openings for exposing a part of the conductive circuits; and
a metal layer formed in the openings of the dielectric layer and at periphery of the active surface of the chip for electrically connecting the conductive bumps of the chip and the conductive circuits.

13. The semiconductor device of claim 12, wherein an adhesive layer is formed between the non-active surface of the chip and the conductive circuits, and the conductive circuits are relatively disposed at periphery of the adhesive layer.

14. The semiconductor device of claim 12, wherein the conductive circuits are formed as an Au/Ni/Au structure, the dielectric layer is made of one of an epoxy resin and polyimide, and the metal layer comprises a copper layer, a nickel layer and a solder layer.

15. The semiconductor device of claim 12, wherein the openings of the dielectric layer are spaced away from sides of the chip such that the sides of the chip are covered by the dielectric layer.

16. The semiconductor device of claim 12, wherein the metal layer on the active surface of the chip of the semiconductor device is electrically connected to the conductive circuits on the non-active surface of the chip of another semiconductor device by a thermal compression to form a multi-chip stack structure.

17. The semiconductor device of claim 16, wherein an underfill material is filled in spacing between the semiconductor devices of the stack structure.

18. The semiconductor device of claim 12, further comprising an insulation layer formed on the active surface of the chip and the metal layer.

19. The semiconductor device of claim 18, further comprising conductive components mounted on outer surface of the conductive circuits of the non-active surface of the chip.

20. The semiconductor device of claim 19, wherein the insulation layer has openings for exposing the metal layer such that conductive components mounted on the conductive circuits of another semiconductor device are electrically connected to the metal layer exposed from the openings of the insulation layer.
